(19) United States
(12) Patent Application Publication
(10) Pub. No.: US 2015/0263089 A1
(43) Pub. Date: Sep. 17, 2015

(54) NON-PLANAR SEMICONDUCTOR DEVICE WITH P-N JUNCTION LOCATED IN SUBSTRATE

(71) Applicant: GLOBALFOUNDRIES INC., GRAND CAYMAN (KY)

(72) Inventors: Jagar SINGH, Clifton Park, NY (US); Andy WEI, Queensbury, NY (US)

(21) Appl. No.: 14/206,203

(22) Filed: Mar. 12, 2014

(51) Int. Cl. H01L 29/06; H01L 29/66

(52) U.S. Cl. CPC H01L 29/0688; H01L 29/66136

(57) ABSTRACT

A non-planar diode is fabricated, with an n- or p-type raised structure, such as a fin, coupled to the substrate. A well of an opposite type is located under the raised structure, along with an area having additional impurity, located directly under the raised structure, and within the well. This additional implant creates a p-n junction within the substrate, the non-planar diode having an ideality factor in a range of 1 to about 1.05.

### BACKGROUND OF THE INVENTION

1. Technical Field

The present invention generally relates to integrated circuits and methods of fabricating integrated circuits, and more particularly, methods of fabricating a non-planar semiconductor device with p-n junction located in the substrate, and an absence of p-n junctions in the raised structure(s) or fin(s).

2. Background Information

As is known, integrated circuits including, for instance, reference voltage circuits typically provide a steady reference voltage which will not be varied by, for instance, manufacturing processes, temperature or the power supply voltage. The steady reference voltage, thus, often results in such reference voltage circuits being applicable in a wide range of applications such as, for instance, voltage regulators or references in analog, mixed mode and memory circuits such as, data converters, oscillators, power management circuits, dynamic random access memory (DRAM) and flash memories. However, there is a continuous need for improved reference voltage circuits with reduced leakage current for use, for instance, in integrated circuits.

### SUMMARY OF THE INVENTION

The shortcomings of the prior art are overcome and additional advantages are provided through the provision, in one aspect, of a method of fabricating a non-planar semiconductor device. The method includes providing a non-planar semiconductor structure, the structure including a semiconductor substrate, one or more raised semiconductor structures of n-type or p-type coupled to the substrate, and a well of a type opposite that of the one or more raised structures and located in the substrate under the one or more raised structures. The method further includes creating an area of one or more additional impurities of a same type as the one or more raised structures, the area being located in the well directly under the one or more raised structures, wherein the area occupies less space than the well, and wherein there is an absence of p-n junctions in the one or more raised structures.

In accordance with another aspect, a method includes providing a non-planar semiconductor structure. The structure includes a semiconductor substrate, at least one raised structure of at least one of n-type and p-type coupled to the substrate, and locating a p-n junction in the substrate for at least one of the at least one raised structure while avoiding locating a p-n junction in the at least one of the at least one raised structure.

In accordance with yet another aspect, a non-planar semiconductor diode is provided, the non-planar semiconductor diode including a semiconductor substrate and at least one raised semiconductor structure coupled to the substrate, the diode having an ideality factor in a range of 1 to about 1.05.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional elevational view of one example of a non-planar semiconductor structure obtained at an intermediate stage of fabrication of one or more integrated circuits, the semiconductor structure including doped raised semiconductor structures and a well of opposite type therebelow.

FIG. 2 is a cross-sectional elevational view of one example of a non-planar semiconductor structure obtained at an intermediate stage of fabrication of one or more integrated circuits, with multiple doped raised semiconductor structures and one or more areas of additional impurities disposed directly thereunder, within a well of opposite type in a bulk semiconductor substrate, in accordance with one or more aspects of the present invention.

FIG. 3 is an alternate embodiment of the structure of FIG. 1, with an n-type group of raised structures and a p-type group of raised structures coupled to the semiconductor substrate with areas of additional impurities directly below each of the raised structure groups, the impurity areas both being situated within a p-type well, which is itself situated within an n-type well, in accordance with one or more aspects of the present invention.

FIG. 4 is a three-dimensional plan view of another example of a non-planar diode, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, the term “connected,” when used to refer to two physical elements, means a direct connection between the two physical elements. The term “coupled,” however, can mean a direct connection or a connection through one or more intermediary elements.

Reference is made below to the drawings, which are not drawn to scale for ease of understanding, wherein the same reference numbers are used throughout different figures to designate the same or similar components.

For voltage reference circuits, the need is for a stable and constant output (reference) voltage that is largely independent of power supply voltages and temperature. To achieve such a reference voltage, leakage current must be low (i.e., approaching ideal base-emitter behavior). Voltage reference circuits included on chip can be used to monitor device performance. For example, as explained herein, non-planar bipolar devices can be fabricated using FinFET processing steps, and the temperature behavior of the junctions of these bipolar devices can provide a good temperature reference for circuit applications, as with band-gap references. In such a case, it has been found that the temperature measurement can depend, fairly accurately, on the ideality factor η, which in this scenario, is ideally one, or as close to one as possible; more specifically, an ideality factor in a range of 1 to about 1.05. In one example, an ideality factor in a range of 1-1.04 can be used. The present invention reduces or eliminates junction leakage in a diode (e.g., a diode used as a performance indicator) by effectively pushing the p-n junction down into the substrate from what otherwise would be located in the body of the fin (or, more generally, the raised structure).

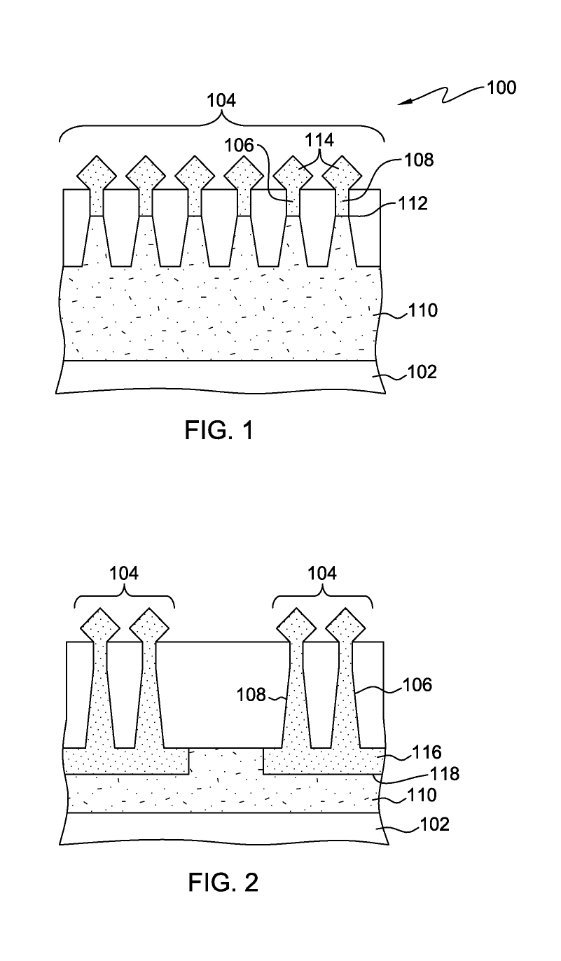

FIG. 1 is a cross-sectional elevational view of one example of a semiconductor structure obtained at an intermediate stage of fabrication of one or more integrated circuits, in accordance with one or more aspects of the present invention. At the point of fabrication depicted in FIG. 1, semiconductor structure 100 includes a semiconductor substrate 102, for example, a bulk semiconductor material, e.g., a bulk silicon wafer. In one example, semiconductor substrate 102 may include any silicon-containing substrate including, but not limited to, silicon (Si), single crystal silicon, polycrystalline silicon (Poly-Si), amorphous Si, silicon-on-nothing (SON), silicon-on-insulator (SOI), or silicon-on-replacement insulator (SRI) substrates and the like. Semiconductor substrate 102 may in addition or instead include various isolations, dopings and/or device features. The substrate may include other suitable elementary semiconductors, such as, for example, crystalline germanium, a compound semiconductor such as silicon carbide (SiC), gallium arsenide (GaAs), gallium antimonide (GaSb), gallium phosphide (GaP), indium phosphide (InP), indium arsenide (InAs), and/or indium antimonide (InSb) or combinations thereof; an alloy semiconductor including GaAsP, AlInAs, GaInAs, GaInP or GaInAsP or combinations thereof. Semiconductor substrate 102 may be planar substrate, or three-dimensional, such as, FINs or Nanowires.

Continuing with FIG. 1, semiconductor structure 100 may further include one or more fins 104 coupled to substrate 102. In the present example, the one or more fins 104, e.g., fins 106 and 108 , made of any suitable material, may be implanted with a dopant with such as, for example, an n-type dopant, to create the n-type doped fins coupled to substrate 102. The n-type dopant refers to the addition of impurities to, for instance, an intrinsic semiconductor material of the fins, which contribute more electrons to the intrinsic material, and may include (for instance) phosphorus, antimony or arsenic. Alternatively, some or all of the one or more fins 104, e.g., fins 106 and 108 may instead be implanted with a dopant such as, for example, a p-type dopant, to create the p-type doped fins coupled to the substrate. Note that as used herein, p-type dopant refers to the addition of an impurity to an intrinsic (undoped) semiconductor material of the fins to create deficiencies of valence electrons within the intrinsic material. Examples of a p-type dopant may include boron, aluminum, gallium or indium, being added to fins 104.

Continuing further with FIG. 1, semiconductor structure 100 further includes a well 110 being located within substrate 102, and under fins 104. Note that, the well 110 is implanted with a dopant type that is opposite of the dopant type used to implant fins 104. The well may be created where a portion of substrate 102 is implanted with a p-type dopant, to create the p-type doped well, if fins 104 are implanted with an n-type dopant. Examples of a p-type dopant may include boron, aluminum, gallium or indium, being added to a portion of substrate 102. Although the present example includes a p-type well 110 fabricated over substrate 102, one skilled in the art will appreciate that an n-type well could instead be fabricated over the substrate, if fins 104 are implanted with a p-type dopant. In such an example, a portion of substrate 102 may be implanted with n-type dopants such as phosphorus, antimony or arsenic.

Continuing further with FIG. 1, fins 104, for instance, fins implanted with n-type dopants (e.g., n+ doped) and the underlying well 110, where the well has been doped with p-type dopants, together creates a p-n junction 112 within the body of fins 104. Note that p-n junction 112 created within the fins is located above the underlying well 110, which can lead to an increased leakage current. One skilled in art will note that, this increased leakage current disadvantageously affects the ideality factor, resulting in the ideality factor to be greater than about 1. Further, fins 104, for instance, the n-type doped fins, may include an epitaxial material 114 grown thereon of a same type as fins 104, as depicted further in FIG. 1. In one example, substrate 102 is a bulk silicon wafer, and the structure of FIG. 1 is a bipolar device fabricated with FinFETs on the same wafer. The epitaxial material may be grown on both types of devices, preferably in a common process, in order to minimize processing steps.

To combat the leakage current and other negative effects of locating the junction in the body of the fin, the present invention effectively pushes the junction down into the substrate by extending the n-type doping area of the fin. This is done, for example, by implanting one or more additional impurities within an area 116, the area being located within well 116, directly under fins 104, as depicted in FIG. 2. Note that, area 116 which, in one example, occupies less space than well 110, may be implanted with a same type of additional impurities, for instance, dopants, as the dopants used to implant fins 104. In one example, if fins 104 are doped with an n-type dopant (e.g., n+ doped) such as, for example, phosphorus, arsenic or antimony, to create n-type doped fins, the area 116 , located directly under fins 104, and still within well 110, may also be doped with n-type dopants (e.g., also n+ doped). This additional doping with impurities in area 116 located within well 110, directly under fins 104 will, advantageously facilitate in creating a stable p-n junction diode, the junction being located at interface 118 between area 116 and p-well 110, under fins 104, and deeper into, for instance, the bulk silicon region. Without doped area 116, the p-n junction, as discussed above in connection with FIG. 1, would otherwise be located in the bodies of fins 104. Such a stable p-n junction diode 116 may further facilitate minimizing surface defects and other sidewall impacts, caused during formation of the fins. Locating the p-n junction in the substrate also improves the emitter-base voltage, and enables the ideality factor of the diode to be one or about one. The above solution can be incorporated into fabrication lines that include one or more other non-planar or fin-based semiconductor devices. In one example, the semiconductor structure may include p-n junction diodes and other devices (e.g., FINFET) being built together on the same semiconductor wafer.

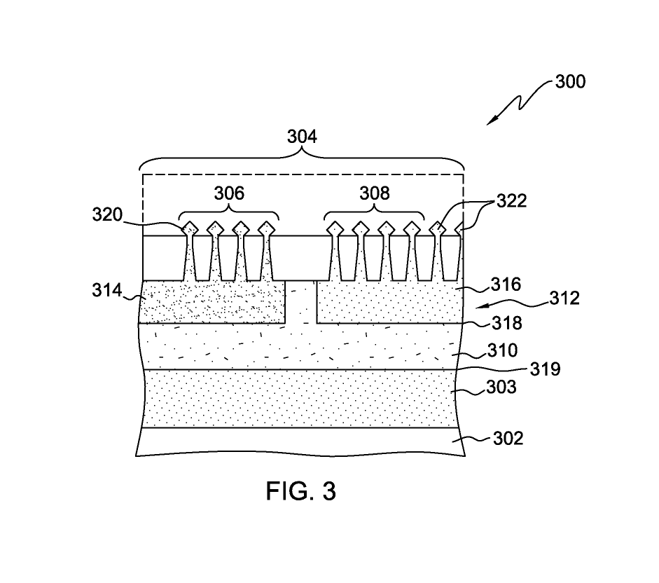

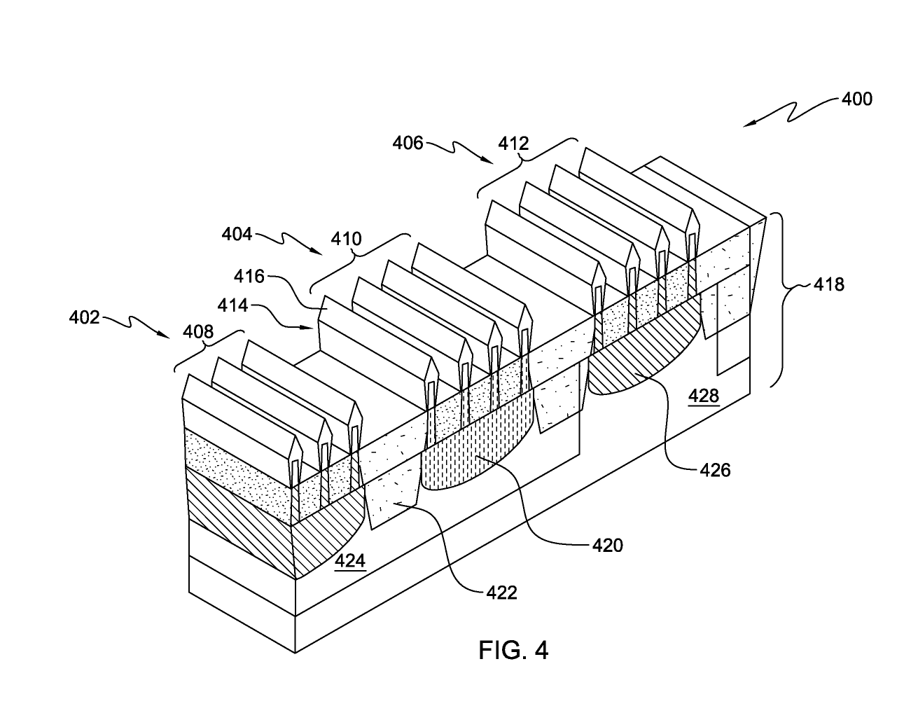

FIG. 3 is an alternate embodiment of the structure of FIG. 1, where a non-planar diode is fabricated, in accordance with one or more aspects of the present invention. At the point of fabrication shown in FIG. 3, semiconductor structure 300 (in this example, an NPN diode) includes a semiconductor substrate 302, for example, a bulk semiconductor material, e.g., a bulk silicon wafer. In one example, semiconductor substrate 302 may include any silicon-containing substrate including, but not limited to, silicon (Si), single crystal silicon, polycrystalline silicon (Poly-Si), amorphous Si, silicon-on-nothing (SON), silicon-on-insulator (SOI), or silicon-on-replacement insulator (SRI) substrates and the like. Semiconductor substrate 302 may in addition or instead include various isolations, dopings and/or device features. In this example, a portion 303 of substrate 302 is n-type doped and acts as the collector of the diode. The substrate may include other suitable elementary semiconductors, such as, for example, crystalline germanium, a compound semiconductor such as silicon carbide (SiC), gallium arsenide (GaAs), gallium antimonide (GaSb), gallium phosphide (GaP), indium phosphide (InP), indium arsenide (InAs), and/or indium antimonide (InSb) or combinations thereof; an alloy semiconductor including GaAsP, AlInAs, GaInAs, GaInP or GaInAsP or combinations thereof. Semiconductor substrate 302 may be planar substrate, or three-dimensional, such as, FINS or Nanowires.

Continuing with FIG. 3, as noted above, semiconductor structure 300 includes an n-type well 303 in substrate 302 that will act as a collector for the NPN diode. The structure 300 further includes one or more raised semiconductor structures 304, e.g., raised structures 306 and 308, coupled to semiconductor substrate 302. As used herein, the term “raised semiconductor structure” refers to a structure that is raised with respect to the substrate to which it is coupled, creating a non-planar or three-dimensional structure (versus planar). In one example, such a raised structure takes the form of a “fin.” One or more of the raised semiconductor structures may include a p-type doped structure 306 (e.g., p+ doped), where a portion of the raised semiconductor structure may be implanted with a dopant such as, for example, a p-type dopant, to create the p-type doped raised structure. Note that as used herein, p-type dopant refers to the addition of an impurity to the bulk (undoped) raised structure to create deficiencies of valence electrons. Examples of a p-type dopant may include boron, aluminum, gallium or indium, being added to a portion of the raised structure. In addition, one or more other of the raised semiconductor structures 304 may include an n-type doped structure 308 (e.g., n+ doped), where a portion of the raised semiconductor structure may be implanted with a dopant such as, for example, an n-type dopant, to create the n-type doped raised structure. The n-type dopant refers to the addition of impurities to, for instance, an intrinsic (undoped) semiconductor material of the raised structure, which contribute more electrons to an intrinsic material, and may include (for instance) phosphorus, antimony or arsenic.

Continuing further with FIG. 3, as discussed above, semiconductor structure 300 further includes a p-type well 310 being located within well 303, and under raised structures 304. Examples of a p-type dopant may include boron, aluminum, gallium or indium, being added to a portion of substrate 302. Although in the present example, the emitter (raised structures 308 and area 316) is n-type and well 310 is p-type fabricated within n-type well 303 and over substrate 302 to create the NPN diode, one skilled in the art will appreciate that the various sections shown would be of opposite type for a PNP transistor, which could be fabricated on the same substrate 302.

One or more additional impurities may be further be implanted within areas 314 and 316, each being located within well 310, directly under their respective same-type raised structures 306 and 308. Note that areas 314 and 316 (collectively, area 312) which, in one example, occupies an area smaller than well 310, may be implanted with a same type of additional impurities, for instance, the same dopants (and, e.g., concentration) as the dopants used to implant raised structures 306 and 308. In one example, if raised structures 306 are doped with a p-type dopant, such as, for example, boron, aluminum, gallium and/or indium, the area located directly under raised structures 306 and in direct contact with raised structures 306, may also be doped with a p-type dopant. Similarly, if raised structures 308 are doped with an n-type dopant such as, for example, phosphorus, arsenic or antimony, to create n-type doped raised structures, the area 316 located within well 310, located directly under raised structures 308 may also be doped with n-type dopants. This additional doping with impurities in area 312 located within well 310, directly under raised structures 304 will, advantageously facilitate in extending the p-n junction down into the substrate, reducing or eliminating leakage current caused by locating the p-n junction in the fin bodies, the substrate location creating a more stable p-n junction 318. As discussed previously, locating the junction in the substrate, versus in the raised structures or fins, further facilitates in minimizing surface defects and other sidewall impacts, experienced during formation of the fins, improving the emitter-base voltage, and enabling the ideality factor of the diode to be one or about one. As one skilled in the art will know, the other junction 319 of the NPN diode of this example is located at the interface between well 310 and well 303.

Continuing further with FIG. 3, raised structures 304, for instance, p-type doped raised structures 306 and n-type doped raised structures 308, may further have epitaxial material of a same type (and, e.g., concentration) grown thereon. In one example, p-type doped raised structures 306 may have p-type doped epitaxial material 320 grown on top surfaces thereof. In another example, n-type doped raised structures 308 may have n-type doped epitaxial material 322 grown on top surfaces thereof. Note that the NPN diode of the present example (more generally, any fin-based semiconductor structure utilizing the strategically located junction therein) may be fabricated on a same substrate (e.g., a bulk silicon substrate) as at least one other type of fin-based semiconductor device. In one example, the semiconductor structure may include devices, for instance, p-n junction diode and other devices (e.g., FINFET) being built together on the same semiconductor wafer. Further, the different devices can share common processes, such as epitaxial growth on top of the raised structures common to both devices.

FIG. 4 is a three-dimensional plan view of another example of a non-planar diode, in accordance with one or more aspects of the present invention. Shown in FIG. 4 is PNP diode structure 400, including an emitter 402, base 404 and collector 406. Each of the three components includes a plurality of raised structures (e.g., fins). For example, emitter 402 includes fins 408, base 410 includes fins 410 and collector 406 includes fins 412. As with the other examples, each fin (e.g., fin 414 in base 404) includes epitaxial material grown thereon, in this example, diamond-shaped epitaxial structures (e.g., diamond-shaped epitaxial structure 416). Between the fins of a given group is an insulator, for example, an oxide. Directly underneath each group of fins is an implant region within substrate 418 of the same n or p-type as the fin group. For example, directly under fins 410 of base 404 is implant region 420 of the same type as fins 410. In this example, the implant regions are relatively deep, about 50 nm to about 500 nm. Between the implant regions are isolation regions (e.g., isolation region 422), for example, shallow trench isolation (STI) regions. The implant regions for emitter 402 and base 404 are situated within a well 424, in this example, an n-type well. Well 424 and implant region 426 for collector 406 are situated within a region 428 of opposite type than well 424, which region may be another larger well, or a doped portion (or all) of the substrate.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a non-planar semiconductor structure, the structure comprising: a semiconductor substrate, one or more raised semiconductor structures of n or p-type coupled to the substrate; a well of a type opposite that of the one or more raised structures and located in the substrate under the one or more raised structures; and
creating an area of one or more additional impurities of a same type as the one or more raised structures, the area being located in the well directly under the one or more raised structures, wherein the area occupies less space than the well, and wherein there is an absence of p-n junctions in the one or more raised structures.

2. The method of claim 1, wherein the non-planar semiconductor structure further comprises epitaxy of a same type as the one or more raised structures at a top of at least one of the one or more raised structures.

3. The method of claim 1, wherein the well is p-type and wherein the one or more raised structures and the area are n-type.

4. The method of claim 1, wherein the well is n-type and wherein the one or more raised structures and the area are p-type.

5. The method of claim 1, wherein the non-planar semiconductor structure comprises a p-n junction diode with an ideality factor in a range of 1 to about 1.05.

6. The method of claim 1, wherein the non-planar semiconductor substrate comprises a bulk semiconductor substrate, wherein the one or more raised structures comprise a plurality of raised structures, wherein the well comprises one or more wells, and wherein the area comprises one or more areas of one or more additional impurities of a same type as one or more raised structures of the plurality of raised structures located directly thereabove.

7. The method of claim 6, wherein the non-planar semiconductor structure further comprises at least one other type of raised structure-based semiconductor device.

8. A method, comprising:
providing a non-planar semiconductor structure, the structure comprising: a semiconductor substrate; at least one raised structure coupled to the substrate, each raised structure being one of n-type and p-type; and
locating a p-n junction in the substrate for one or more of the at least one raised structure while avoiding locating a p-n junction in the one or more of the at least one raised structure, the locating comprising:
creating a well of a type opposite the at least one raised structure the well situated in the substrate below the at least one raised structure; and
creating an area smaller than the well of a same type as the at least one raised structure, the area located in the well directly under and in contact with the at least one raised structure such that the p-n junction in the substrate comprises an interface between the well and the area.

9. (canceled)

10. The method of claim 8, wherein the structure further comprises epitaxy on a top surface of the at least one raised structure of a same type as the raised structure.

11. The method of claim 8, wherein the semiconductor substrate comprises a bulk semiconductor substrate, wherein the at least one raised structure comprises a plurality of raised structures, wherein the locating comprises locating a p-n junction for at least two of the plurality of raised structures in the bulk substrate, wherein creating the well comprises creating one or more wells, and wherein creating an area comprises creating one or more areas of a same type as the at least two of the plurality of raised structures associated therewith.

12. The method of claim 11, wherein at least one of the plurality of raised structures other than the at least two of the plurality of raised structures comprises at least one other type of semiconductor device.

13. A non-planar semiconductor diode, comprising a semiconductor substrate and at least one raised semiconductor structure coupled to the substrate, wherein the diode has an ideality factor in a range of 1 to about 1.05.

14. The non-planar diode of claim 13, wherein the ideality factor is in a range of 1-1.04.

15. The non-planar diode of claim 13, wherein a p-n junction of the diode is situated in a semiconductor substrate of the diode, and wherein there is an absence of p-n junction in any raised semiconductor structure of the diode.

16. The non-planar diode of claim 15, further comprising:
at least one raised structure coupled to the substrate of at least one of p-type and n-type;
at least one well of a type opposite the at least one raised structure, the at least one well situated in the substrate under the at least one raised structure; and
at least one area smaller than the at least one well, the at least one area of a same type as and located directly under the at least one raised structure.

17. The non-planar diode of claim 16, further comprising epitaxy of a same type as the at least one raised structure at a top of at least one of the at least one raised structure.

18. The non-planar diode of claim 17, wherein one or more of the at least one well is p-type, and wherein the at least one raised structure and the at least one area are n-type.

19. The non-planar diode of claim 17, wherein one or more of the at least one well is n-type, and wherein the at least one raised structure and the at least one area are p-type.

20. The non-planar diode of claim 13, wherein the non-planar diode comprises one of: N+ to P-type well diode; P+ to N-type well diode; and P-type well to N-type well diode.
